(19) United States
(12) Patent Application Publication
(10) Pub. No.: US 2020/0234928 A1
(43) Pub. Date: Jul. 23, 2020

(54) SEMICONDUCTOR PLASMA PROCESSING EQUIPMENT WITH WAFER EDGE PLASMA SHEATH TUNING ABILITY

(71) Applicant: Applied Materials, Inc., Santa Clara, CA (US)

(72) Inventor: Yogananda Sarode VISHWANATH, Bangalore (IN)

(21) Appl. No.: 16/672,294

(22) Filed: Nov. 1, 2019

Related U.S. Application Data
(60) Provisional application No. 62/793,862, filed on Jan. 17, 2019.

(51) Int. Cl. H01J 37/32; H01L 21/67; H01L 21/687

(52) U.S. Cl. CPC H01J 37/32642; H01L 21/67069; H01J 37/32715; H01L 21/68757; H01L 21/6833; H01J 37/32899; H01L 21/67167; H01J 2237/3343; H01J 37/321; H01L 21/68735

(57) ABSTRACT

Embodiments of the disclosure generally include methods and apparatuses that improve the etch rate uniformity across a surface of a substrate by controlling the shape of a plasma sheath formed across a substrate, such as a semiconductor wafer, during plasma processing. Embodiments of the disclosure will include the adjustment of one or more plasma processing variables and/or the adjustment of the configuration of process kit hardware that is in close proximity to a substrate and/or supports the substrate during processing. Furthermore, embodiments of the disclosure will include replacement of only a small number of consumable parts within the process kit hardware while the remaining parts of the process kit hardware are reused for long periods of time without venting the process chamber. The replacement of the consumable parts can be completed using an automated method of swapping used parts without venting process chamber.

### CROSS-REFERENCE TO RELATED APPLICATIONS

This application claims the benefit to U.S. Provisional Application No. 62/793,862, filed Jan. 17, 2019, which is incorporated by reference herein.

### BACKGROUND

### Field

Embodiments of the present disclosure generally relate to a semiconductor wafer edge plasma sheath tunability, and more specifically, to an etch process hardware design for wafer edge plasma sheath control.

### Description of the Related Art

In semiconductor circuit patterning, a wafer resting on a support may undergo a process that dry (plasma) etches portions of a material deposited on the wafer. Plasma etching is performed by applying radio frequency (RF) electromagnetic energy to a gas containing a chemically reactive element, such as fluorine or chlorine. During etching processes, the plasma, which drives the etching process, may not be uniformly distributed across the substrate surface. The non-uniformity is particularly apparent at the edge of the substrate surface, and is generally caused by the direction of the flux of ions generated in the plasma not being vertical near the edges of the wafer due to a configuration of the plasma sheath formed near the wafer edges. To control the configuration of the plasma sheath near the wafer edges, a biasable edge ring is sometimes provided proximate to the wafer edges. However, traditional edge rings erode over time. As the edge ring erodes, plasma uniformity across the wafer surface decreases, thereby negatively affecting wafer processing. Since there is a direct correlation between plasma uniformity and the quality of processed wafers, traditional process chambers require frequent replacement of edge rings to maintain plasma uniformity. However, the frequent replacement of edge rings results in undesirable downtime for preventative maintenance, and leads to increased costs for consumable components such as the edge rings.

Therefore, there is a continual need for an improved controllability of various aspects of the plasma sheath while retaining the RF electromagnetic energy to maintain the plasma sheath. There is also a need for an edge ring that has a reduced cost and a need in the art for methods and apparatuses that improve plasma uniformity.

### SUMMARY

Embodiments of the disclosure generally include methods and apparatuses that improve the etch rate uniformity across a surface of a substrate by controlling the shape of a plasma sheath formed across a substrate, such as a semiconductor wafer, during plasma processing. Embodiments of the disclosure will include the adjustment of one or more plasma processing variables and/or the adjustment of the configuration of process kit hardware that is in close proximity to a substrate and/or supports the substrate during processing. Furthermore, embodiments of the disclosure will include replacement of only a small number of consumable parts within the process kit hardware while the remaining parts of the process kit hardware are reused for long periods of time without venting the process chamber. The replacement of the consumable parts can be completed using an automated method of swapping used parts without venting process chamber. Thus, the overall cost for plasma processing in the process chamber is reduced.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a process chamber according to one embodiment.

FIGS. 2A, 2B, 2C are schematic partial cross-sectional views of a substrate support assembly according to one embodiment.

FIGS. 3A and 3B are schematic partial cross-sectional views of a process kit according to one embodiment.

FIGS. 4A, 4B, and 4C are schematic partial cross-sectional views of a process kit according to one embodiment.

FIGS. 5A, 5B, 5C, and 5D are schematic partial cross-sectional views of a process kit according to one embodiment.

FIGS. 6A, 6B, and 6C are schematic partial cross-sectional views of the process kit according to one embodiment.

FIGS. 7A, 7B, and 7C are schematic partial cross-sectional views of the process kit according to one embodiment.

FIGS. 8A and 8B are a side view and a cross-sectional view of an edge ring according to one embodiment.

FIGS. 8C, 8D, 8E, and 8F are shapes of indents according to one embodiment.

FIGS. 9A and 9B are schematic partial cross-sectional views of a process kit according to one embodiment.

FIGS. 10A and 10B are a cross-sectional view and a top view of a movable ring according to one embodiment.

FIGS. 10C and 10D are a top view and a cross-sectional of a support ring according to one embodiment.

FIG. 11 is a schematic cross-sectional view of a combined system including a process kit, a lift mechanism, and an actuating mechanism according to one embodiment.

FIG. 12 is a schematic top view of a processing system according to one embodiment.

FIG. 13A is a schematic cross-sectional view of a process kit according to one embodiment.

FIGS. 13B and 13C are a schematic top view and a cross-sectional view of a process kit held by a carrier ring according to one embodiment.

FIGS. 14A and 14B are schematic views of a robot blade according to one embodiment.

FIG. 15 is a flowchart of a method according to one embodiment.

FIG. 16 is a flowchart of a method according to one embodiment.

FIG. 17 is a flowchart of a method according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

Embodiments of the disclosure generally include methods and apparatuses that improve the etch rate uniformity across a surface of a substrate by controlling the shape of a plasma sheath formed across a substrate, such as a semiconductor wafer, during plasma processing. Embodiments of the disclosure will include the adjustment of one or more plasma processing variables and/or the adjustment of the configuration of process kit hardware that is in close proximity to a substrate and/or supports the substrate during processing. Thus, the uniformity of the plasma sheath across the wafer surface can be controlled, thereby increasing wafer processing yield. Furthermore, embodiments of the disclosure will include replacement of only a small number of consumable parts within the process kit hardware while the remaining parts of the process kit hardware are reused for long periods of time without venting the process chamber. The consumable parts, which become eroded or attacked during plasma processing, are typically replaced after a much shorter period of time, such as about a hundred substrates to about a few thousand substrates that are processed within the process chamber. The replacement of the consumable parts can be completed using an automated method of swapping used parts without venting process chamber. Thus, the overall cost for plasma processing in the process chamber is reduced.

Moreover, process non-uniformities often exist across the surface of the substrate and may be significant at the perimeter or edge of the substrate after performing conventional plasma processing steps. These non-uniformities at the perimeter may be attributable to electric field termination effects and are sometimes referred to as edge effects. Movable edge ring with RF coupling provides compensation for edge ring wear over PM cycle (preventive maintenance), step-to-step tuning for CD profile (critical dimension), and faster edge yield tuning. Therefore, in some embodiments, during a plasma process being performed in a process chamber (e.g., a dry etching process), a process kit containing at least set of edge rings may be provided to favorably influence uniformity at the substrate perimeter or edge.

As an initial matter, in the following description, an orthogonal coordinate system including an X-axis, a Y-axis, and a Z-axis is used to help describe the relative orientation of the various described components, and is not intended to limiting as to the scope of the disclosure provided herein.

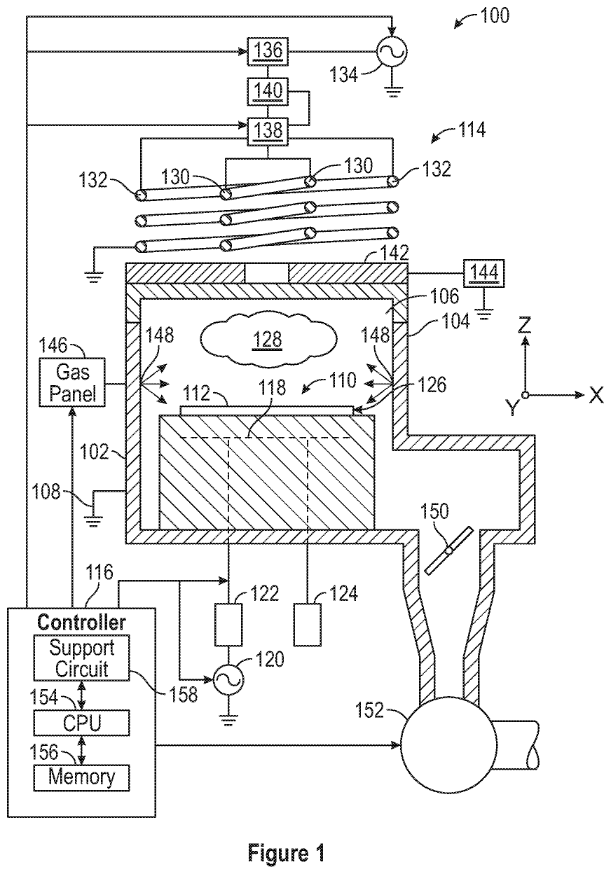

FIG. 1 is a schematic cross-sectional view of a process chamber 100, according to one embodiment. The process chamber 100 includes a chamber body 102 and a lid 104 disposed thereon that together define an inner volume 106, or process volume 106. The chamber body 102 is typically coupled to an electrical ground 108. A substrate support assembly 110 is disposed within the inner volume 106 to support a substrate 112 thereon during processing. The process chamber 100 also includes an inductively coupled plasma apparatus 114 for generating plasma within the process chamber 100, and a controller 116 adapted to control the process chamber 100.

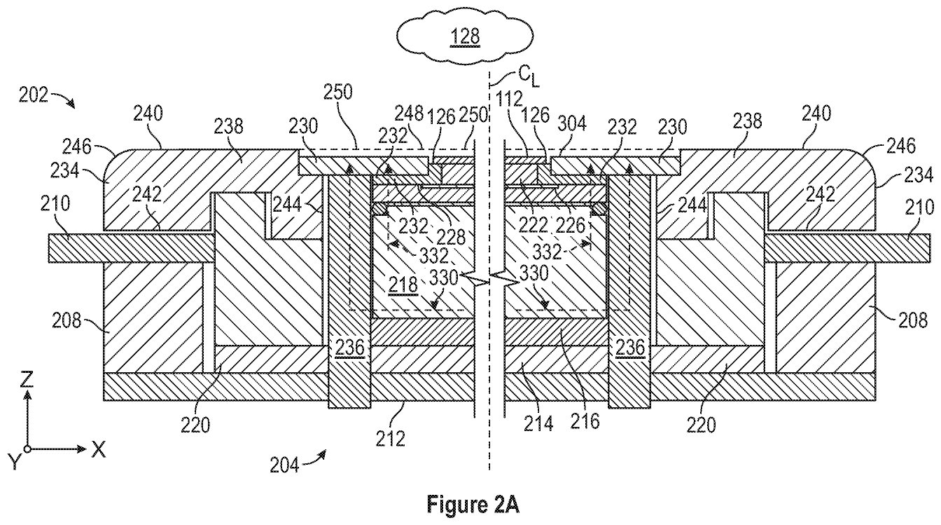

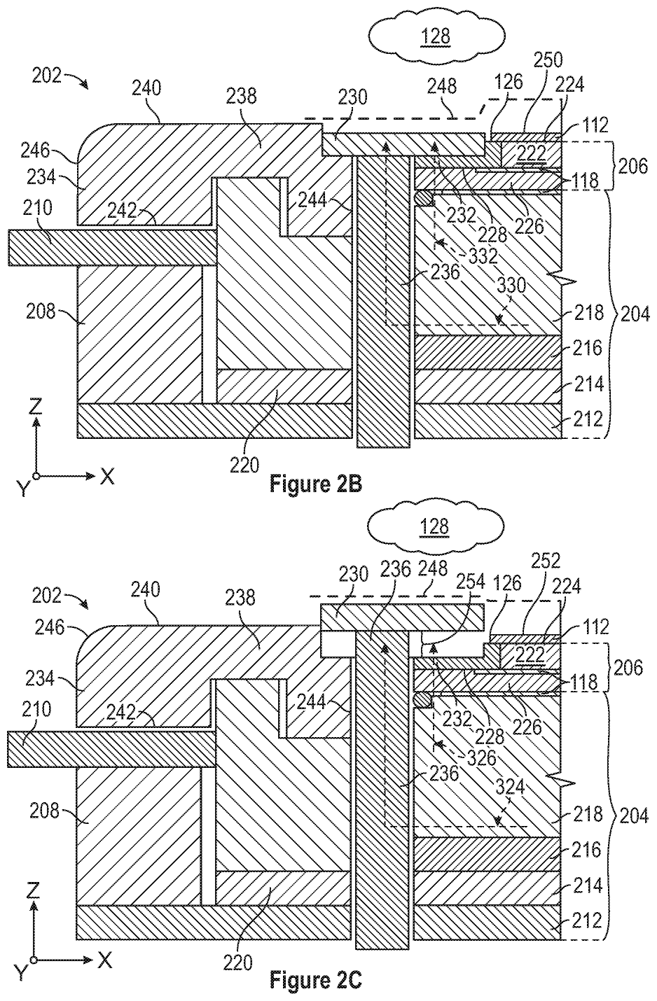

The substrate support assembly 110 includes one or more electrodes 118 coupled to a bias source 120 through a matching network 122 to facilitate biasing of the substrate 112 during processing. The bias source 120 may be a source of up to about 5000 Watts of RF energy at a frequency of, for example, approximately 13.56 MHz, although other frequencies and powers may be provided as desired for particular applications. The bias source 120 may be capable of producing either or both of continuous or pulsed RF power. In some embodiments, the bias source 120 may be a DC or pulsed DC source. In some embodiments, the bias source 120 may be capable of providing multiple RF frequencies. The one or more electrodes 118 may be coupled to a chucking power source 124 to facilitate chucking of the substrate 112 during processing. The substrate support assembly 110 includes a process kit (not shown in FIG. 1) that surrounds the outer edge 126 of the substrate 112. FIGS. 2A-7C, 9A, 9B, 11, and 12A illustrate various configurations of a process kit that is disposed at the outer edge 126 of the substrate 112 that is disposed on the substrate support assembly 110 shown in FIG. 1. FIGS. 2B-7C, 9A, 9B, and 12A illustrate side cross-sectional views of a left side edge of a process kit disposed on the substrate support assembly 110. While not intending to limit as to the scope of the disclosure provided herein, in some embodiments in which the substrate 112 is circular in shape, the process kit is substantially axially symmetric about a central vertical axis, which is aligned with Z-direction, found at a center of the substrate 112.

An inductively coupled plasma apparatus 114 is disposed above the lid 104 and is configured to inductively couple RF power into the process chamber 100 to generate plasma 128 within the process chamber 100. The inductively coupled plasma apparatus 114 includes first and second coils 130, 132, disposed above the lid 104 in the Z-direction. The relative position, ratio of diameters of each coil 130, 132, and/or the number of turns in each coil 130, 132 can each be adjusted as desired to control the profile or density of the plasma being formed. Each of the first and second coils 130, 132 is coupled to an RF power supply 134 through a matching network 136 via an RF feed structure 138. The RF power supply 134 may be capable of producing up to about 5000 W at a tunable frequency in a range from 50 kHz to 140 MHz, for example, although other frequencies and powers may be utilized as desired for particular applications.

In some embodiments, a power divider 140, such as a dividing capacitor, may be provided between the RF feed structure 138 and the RF power supply 134 to control the relative quantity of RF power provided to the respective first and second coils 130, 132. In some embodiments, the power divider 140 may be incorporated into the matching network 136.

A heater element 142 may be disposed on the lid 104 to facilitate heating the inner volume 106 of the process chamber 100. The heater element 142 may be disposed between the lid 104 and the first and second coils 130, 132. In some embodiments, the heater element 142 may include a resistive heating element and may be coupled to a power supply 144, such as an AC power supply, configured to provide sufficient energy to control the temperature of the heater element 142 within a desired range.

During operation, the substrate 112, such as a semiconductor wafer or other substrate suitable for plasma processing, is placed on the substrate support assembly 110 and process gases supplied from a gas panel 146 through entry ports 148 into the inner volume of the chamber body 102. The process gases are ignited into plasma 128 in the process chamber 100 by applying power from the RF power supply 134 to the first and second coils 130, 132. In some embodiments, power from the bias source 120, such as an RF or DC source, may also be provided through a matching network 122 to electrodes 118 within the substrate support assembly 110. The pressure within the inner volume 106 of the process chamber 100 may be controlled using a valve 150 and a vacuum pump 152. The temperature of the chamber body 102 may be controlled using liquid-containing conduits (not shown) that run through the chamber body 102.

The process chamber 100 includes the controller 116 to control the operation of the process chamber 100. The controller 116 comprises a central processing unit (CPU) 154, a memory 156, and support circuits 158 for facilitating control of the components of the process chamber 100. The controller 116 may be one of any form of general-purpose computer processor that can be used in an industrial setting for controlling various chambers and sub-processors. The memory 156 is connected to the CPU 154. The memory is a non-transitory computable readable medium, and can be one or more readily available memory such as random access memory (RAM), read only memory (ROM), floppy disk, hard disk, or other form of digital storage. The memory 156 stores software (source or object code) that may be executed or invoked to control the operation of the process chamber 100 in the manner described herein. A software application, which is stored within the memory 156, includes program code that may be executed by processor (i.e., CPU 154) in order to perform various functionalities associated with the control of hardware and software components used in conjunction with the process chamber 100.

FIGS. 2A, 2B, and 2C are schematic partial cross-sectional views of the substrate support assembly 110 according to one embodiment. The substrate support assembly 110 includes a process kit 202, a substrate support 204, an electrostatic chuck 206, a cathode liner 208, and a shield 210. The electrostatic chuck 206 is disposed on a top surface of the substrate support 204 and is surrounded by the process kit 202. The substrate support 204 may include a ground plate 212, an insulating plate 214 disposed on the ground plate 212, a facilities plate 216 disposed on the insulating plate 214, a cooling plate 218 disposed on the facilities plate 216, and a sleeve 220 disposed on the insulating plate 214 surrounding the facilities plate 216, the cooling plate 218, and the electrostatic chuck 206 in the Z-direction. The sleeve 220 may be fabricated from quartz or other dielectric material.

The electrostatic chuck 206 may be bonded to the cooling plate 218 with a bonding material. The one or more electrodes 118 may be embedded in the electrostatic chuck 206. The electrostatic chuck 206 may include a first portion 222 having a first surface 224 for supporting the substrate 112 and a second portion 226 extending radially-outward from the first portion 222. The second portion 226 may include a second surface 228.

The process kit 202 includes an edge ring 230, a support ring 232, and a cover ring 234, and a movable ring 236. The edge ring 230 may be positioned in the X-Y plane (i.e., horizontal plane) concentrically around the first portion 222 of the electrostatic chuck 206 and protect the electrostatic chuck 206 from deposition. The support ring 232 is disposed on the second surface 228 of the second portion 226 of the electrostatic chuck 206 in the Z-direction, and the support ring 232 surrounds the first portion 222 of the electrostatic chuck 206. The support ring 232 may be fabricated from a conductive material, such as silicon, silicon carbide (SiC), or an insulating material such as quartz. The support ring 232 may be positioned concentrically with respect to the first portion 222 of the electrostatic chuck 206. In some embodiments, bulk resistivity of the edge ring 230 and the support ring 232 is between about 0.1 Ohms-cm and about 25 Ohms-cm.

The edge ring 230 may be disposed partially on the support ring 232 and partially on the movable ring 236. The edge ring 230 may be fabricated from a conductive material, such as silicon, silicon carbide (SiC), or other suitable material, which, in some embodiments, is more conductive than the support ring 232. The cover ring 234 may be disposed on the sleeve 220 and the cover ring 234 may surround the edge ring 230 and the support ring 232. The cover ring 234 may be fabricated from an insulating material such as quartz. The cover ring 234 includes an annular body 238 having a top surface 240, a bottom surface 242, an inner surface 244, and an outer surface 246. The inner surface 244 is positioned adjacent the edge ring 230 and the movable ring 236, and is also sometimes referred to herein as an inner edge.

In the process chamber 100, during plasma processing a plasma sheath 248, which has a boundary that is illustrated by the dashed lines, is formed over the substrate 112 being etched and the edge ring 230. A bias voltage V_{DC} applied to the electrode 118 in the substrate support assembly 110 or portions of the substrate support assembly 110 being grounded may be used to control a shape of the plasma sheath 248 near an outer edge 126 of the substrate 112 to compensate for critical dimension uniformity. The plasma sheath 248 is a thin region of strong electric fields formed by space charge that joins the plasma 128 to a boundary with surfaces of the substrate 112 and the edge ring 230. Mathematically, a sheath thickness, d, of the plasma sheath 248 is represented by the Child-Langmuir equation

$$d = \frac{2}{3} {( \frac{ɛ}{l} )}^{\frac{1}{2}} {( \frac{2 e}{m} )}^{\frac{1}{4}} {( {V}_{p} - {V}_{D C} )}^{\frac{3}{4}} ,$$

where i is the ion current density, ε is the permittivity of vacuum, e is the elementary electric charge, and Vp is the plasma potential.

Thus, as shown in FIG. 1, the plasma sheath 248 separates the plasma 128 from the surfaces of the substrate 112 and the edge ring 230. The ions produced in the plasma 128 are accelerated in the plasma sheath 248 and move perpendicular to the boundary of the plasma sheath 248. The distribution of the plasma sheath 248 is affected by a shape and a location of the edge ring 230 since the edge ring 230 is electrically coupled to ground or to an RF biased electrode formed within the substrate support assembly 110. When a top surface of the edge ring 230 is co-planar with a top surface 250 of the substrate 112, the plasma sheath 248 is non-uniformly distributed across the top surface 250 of the substrate 112 and bends at the outer edge 126 of the substrate 112 as shown in FIG. 2A. The bends at the outer edge 126 of the substrate 112 is typically related to the position of the outer surface of the electrode 118 relative of the outer edge 126 of the substrate 112, wherein the outer surface of the electrode 118 is controlled by structural limitations placed on the edge of the electrostatic chuck 206. This plasma non-uniformity at the outer edge 126 of the substrate 112 causes non-uniform process conditions across the surface of the substrate 112, thus leading to a decrease in process yield across the substrate 112.

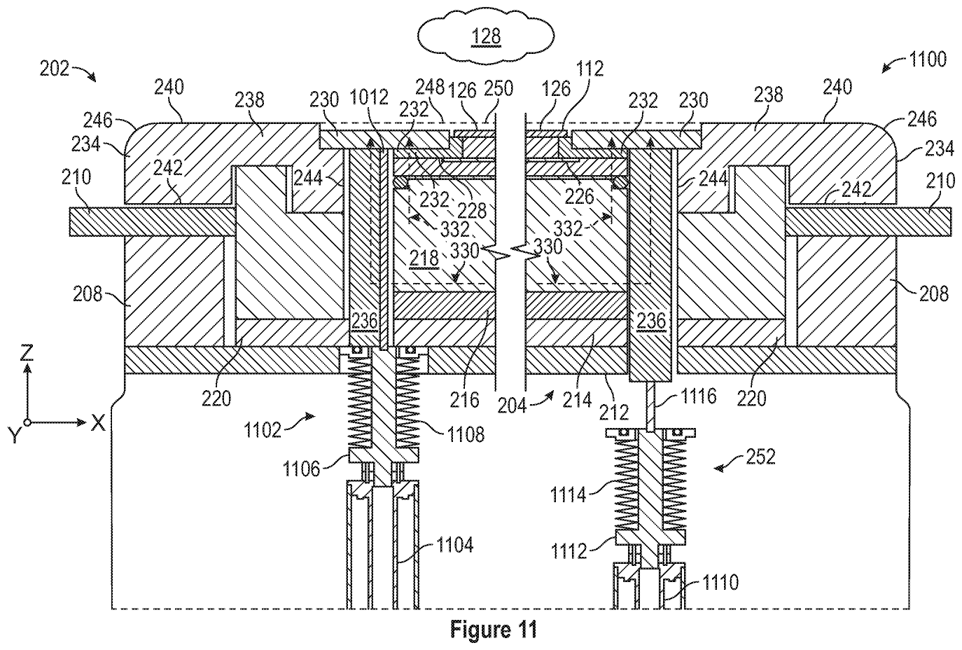

Accordingly, in some embodiments, the edge ring 230 is configured to be raised and lowered by the movable ring 236 to adjust the shape of the plasma sheath 248 formed over the edge ring 230, as shown in FIG. 2C, and near the outer edge 126 of the substrate 112. By adjusting the height of the edge ring 230 relative to the outer edge 126 of the substrate 112 the shape of the plasma sheath 248 can be adjusted to provide a plasma sheath 248 that has a desirable shape at the outer edge 126 of the substrate 112, such as a substantially flat shape when combined with the portion of the plasma sheath 248 disposed over the rest of the substrate 112. In some embodiments, an actuating mechanism 252 (shown in FIG. 11) controlled by a servo motor may raise and lower the movable ring 236 and thus raise and lower the formed plasma sheath 248 between the plasma 128 and the edge ring 230 while maintaining the plasma sheath thickness d nearly constant to achieve a desirable plasma uniformity

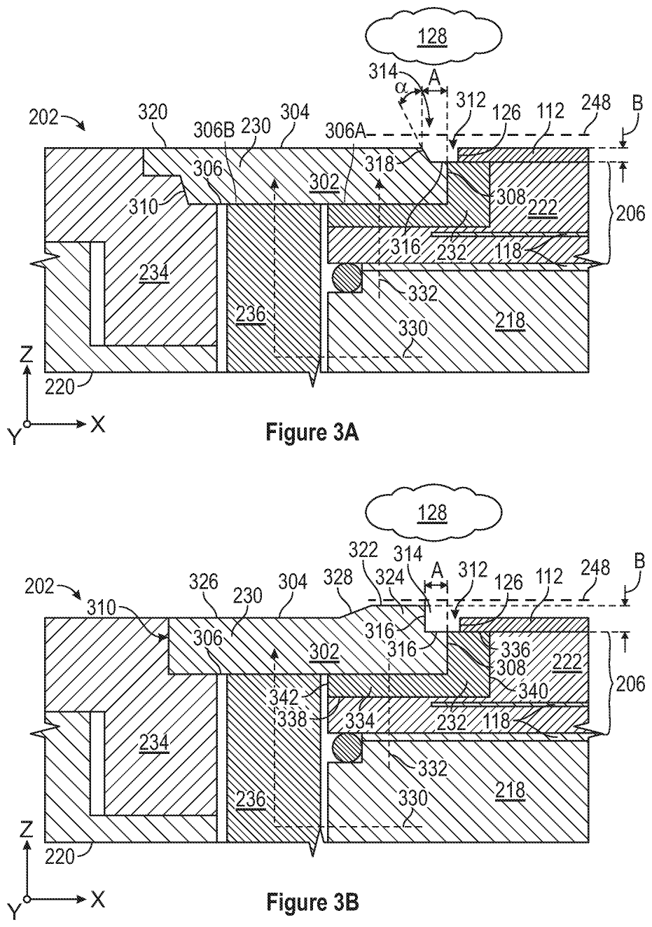

FIG. 3A is a schematic partial cross-sectional view of the process kit 202 according to one embodiment. The edge ring 230 has an annular body 302 surrounding the substrate 112 and having a central axis in the Z-direction. The annular body 302 includes a top surface 304, a bottom surface 306, and an inner surface 308, and an outer surface 310. In some embodiments, the top surface 304 and the bottom surface 306 are substantially parallel to the X-Y plane (i.e., horizontal plane). At least a portion of the inner surface 308 between the top surface 304 and the bottom surface 306 has a diameter that is greater than a diameter of the substrate 112. The bottom surface 306 has a first portion 306A that is supported by the support ring 232, and a second portion 306B that is supported by the movable ring 236. In some embodiments, the inner surface 308 and the outer surface 310 are substantially parallel to the Z-direction. The inner surface 308 surrounds the substrate 112 and is separated radially by a pocket 312. The edge ring 230 may have a recess 314 extending radially-outward from the inner surface 308 and extending partially along the height of the annular body 302 from the top surface 304 towards the bottom surface 306. The recess 314 has a recess bottom surface 316 and a recess edge 318. In some embodiments, the recess bottom surface 316 and the bottom surface 306 are substantially parallel to the X-Y plane (i.e., horizontal plane), and the recess edge 318 is located radially outward from the inner surface 308 by a length of the recess bottom surface 316. In some embodiments, the inner surface 308 is positioned a distance from the outer edge 126 of the substrate 112 that is between about 0.1 mm and about 5 mm in the X-Y plane (i.e., radial direction for a round substrate), and the recess edge 318 is positioned a distance from the outer edge 126 of the substrate 112 that is between about 0.2 mm and about 10 mm in the X-Y plane (i.e., radial direction for a round substrate). While not shown in FIGS. 3A-3B, in some embodiments, at least a portion of edge ring 230 is disposed under the outer edge 126 of the substrate 112 during processing, such that the inner surface 308 is positioned a distance that is between about a negative two millimeters (−2 mm) and about 0 mm in the X-Y plane (i.e., radial direction for a round substrate) underneath the outer edge 126. In some embodiments, the recess edge 318 is tilted from the Z direction (i.e., the central axis of the edge ring 230) by an angle α. In some embodiments, the recess edge 318 is substantially parallel to the Z-direction (i.e., the angle α is 0 degree). In some embodiments, the recess 314 may be a form of a bevel that has the recess edge 318 tilted from the Z direction (i.e., the central axis of the edge ring 230) by the angle α and directly connecting the top surface 304 and the inner surface 208 without the recess bottom surface 314. An angle α can be formed between the recess bottom surface 316 and recess edge 318 that has an angle between about 0 and about 75 degrees, or at an angle between about 1 and about 60 degrees, or even at an angle between about 15 and about 45 degrees.

In some embodiments, the edge ring 230 may have an extended step 320 extending radially-outward from the outer surface 310 and more into the cover ring 234 than the bottom surface 306 and defining a portion of the top surface 304). This extended step 320 will help make it difficult for a plasma 128 to enter a gap formed between movable ring 236 and cover ring 234 and avoid plasma light-up issues. The extended step 320 further alters the capacitive coupling between the edge ring 230 and the cooling plate 218, thus altering and/or extending the plasma sheath 248 at the outer surface of the edge ring 230, and thus altering the plasma sheath 248 near the outer edge 126 of the substrate 112.

In some embodiments, as shown in FIG. 3B, the edge ring 230 includes at least a recess 314 that is defined by the inner surface 308, a recess edge 318 that extends from a recess bottom surface 316 of the recess 314 to a planar top surface 322 (i.e., exposed surface) of a projection 324 formed in the edge ring 230, and the planar top surface 322 is connected to an outer top surface 326 that extends from the outer surface 310 by an angled surface 328. In some embodiments, the planer top surface 322 has a width of between about 0.2 mm and about 5 mm, and the outer top surface 326 has a width of between about 2 mm and about 10 mm. The planar top surface 322 may be higher in the Z-direction than the outer top surface 326 by between 0.2 mm and about 3 mm. A profile of the plasma sheath 248 follows the top surface 304 of the edge ring 230 and the top surface 250 of the substrate 112. Thus, the projection 324 may prevent the profile of the plasma sheath 248 form bending downward at the outer edge 126 of the substrate 112.

Adjusting a width and a depth of the recess 314, a width “A” and a depth “B” of the pocket 312 between the outer edge 126 of the substrate 112 and the inner surface 308, and a shape of the edge ring 230 alters the capacitive coupling between the edge ring 230 and the cooling plate 218 via the support ring 232, represented by capacitive coupling paths 330 and 332. A change in the capacitive coupling paths 330 changes the power coupled between the edge ring 230 and the cooling plate 218 and therefore the voltage that is applied to the edge ring 230. Controlling the voltage applied to the edge ring 230 allows for controlling plasma sheath 248 profile at the outer edge 126 of the substrate to compensate for critical dimension non-uniformity. The width “A” can be between about 0.1 mm and about 10 mm, and the depth “B” can be between about 0.1 mm and about 5 mm in the X-direction, and the thickness in the Z-direction of the edge ring 230 can be between about 3.5 mm and about 25 mm.

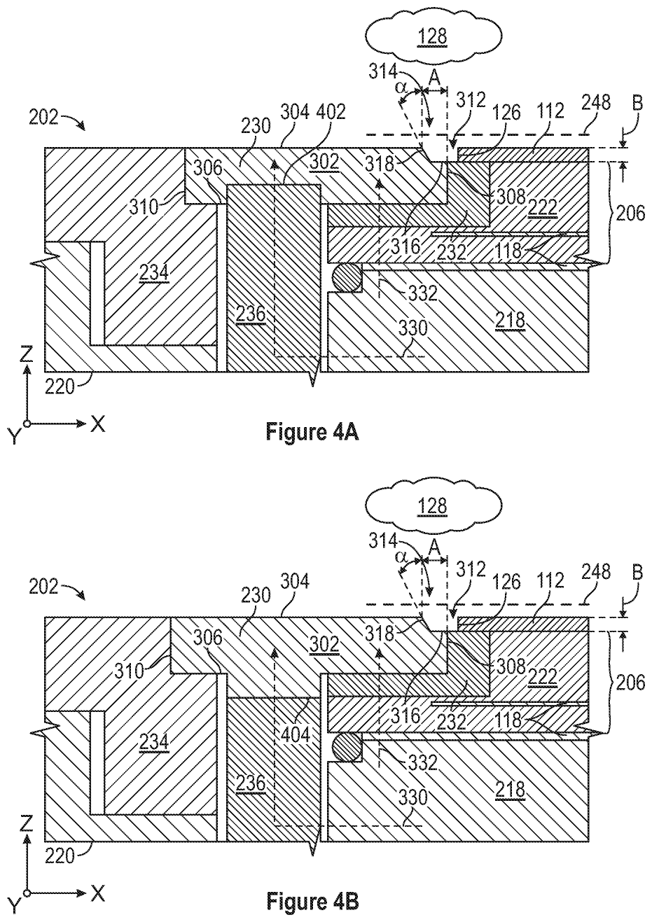

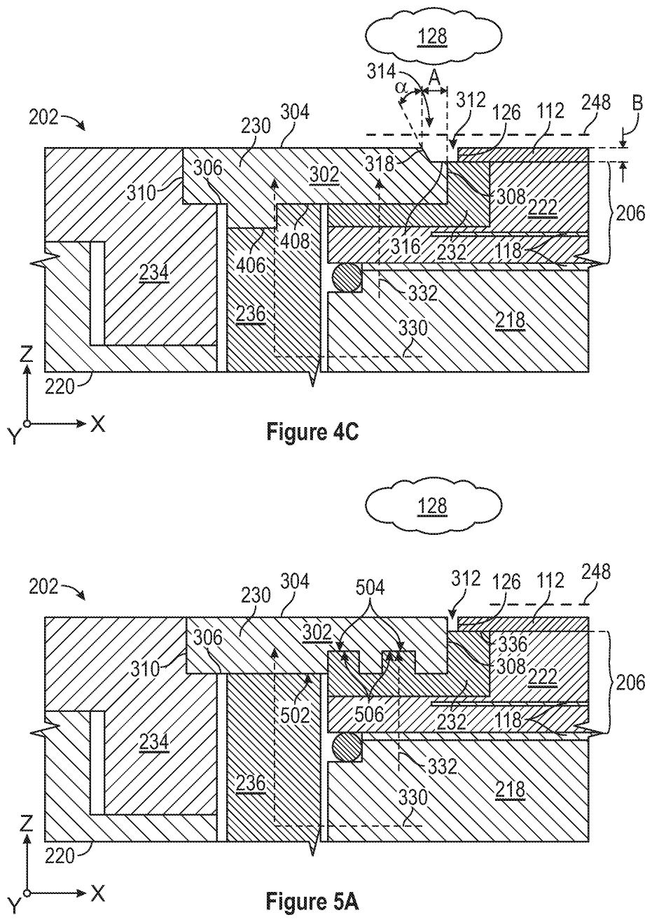

In some embodiments, as shown in FIG. 4A, the edge ring 230 includes at least a recess 402 that extends from the bottom surface 306 towards the top surface 304. The recess 402 may be an annular feature formed on the bottom surface 306. The recess 402 is generally configured to interlock with the movable ring 236, and thus allows the lateral position (i.e., X and/or Y directions) of the movable ring 236 to be controlled relative to the position of the movable ring 236.

In some embodiments, as shown in FIG. 4B, the edge ring 230 includes at least a protrusion 404 that extends from the bottom surface 306 towards the movable ring 236. The protrusion 404 may be an annular feature formed on the bottom surface 306 or may include a series of annular discontinuous regions (e.g., “mesas”) formed on the bottom surface 306. The protrusion 404 is aligned with and contacts the movable ring 236, and thus allows the movable ring 236 to be positioned a further distance away from the plasma 128 during processing to reduce or prevent bombardment and etching of the movable ring 236, which can be biased during processing.

In some embodiments, as shown in FIG. 4C, the edge ring 230 includes a partial protrusion 406 that extends from the bottom surface 306 towards the movable ring 236, and the movable ring 236 includes a partial protrusion 406 that extends from a top surface 502 of the movable ring 236 towards the edge ring 230 such that the top surface 502 of the movable ring 236 contours the bottom surface 306 of the edge ring 230. An edge ring 230 configuration that includes the partial protrusion 406 and partial protrusion 406 can be used to control the lateral position of the edge ring 230 relative to the movable ring 236, and also hide portions of the movable ring 236 from the plasma 128 to reduce or prevent bombardment and etching of the movable ring 236 during processing.

While not intending to be limiting as to the scope of the disclosure provided herein, FIGS. 4A, 4B, and 4C illustrate an edge ring configuration that includes a recess 314. However, in some configurations of the edge ring 230, the edge ring 230 may not include the recess 314. In these configurations, as shown in FIGS. 4A, 4B, and 4C, the angle α may be 90 degree, such that the recess bottom surface 316 is planar with the top surface 304.

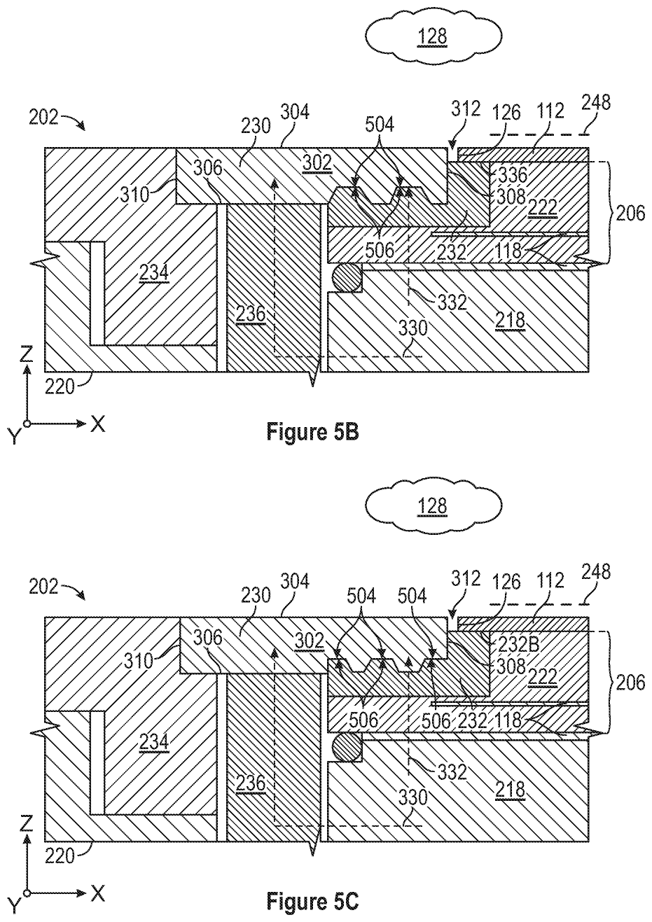

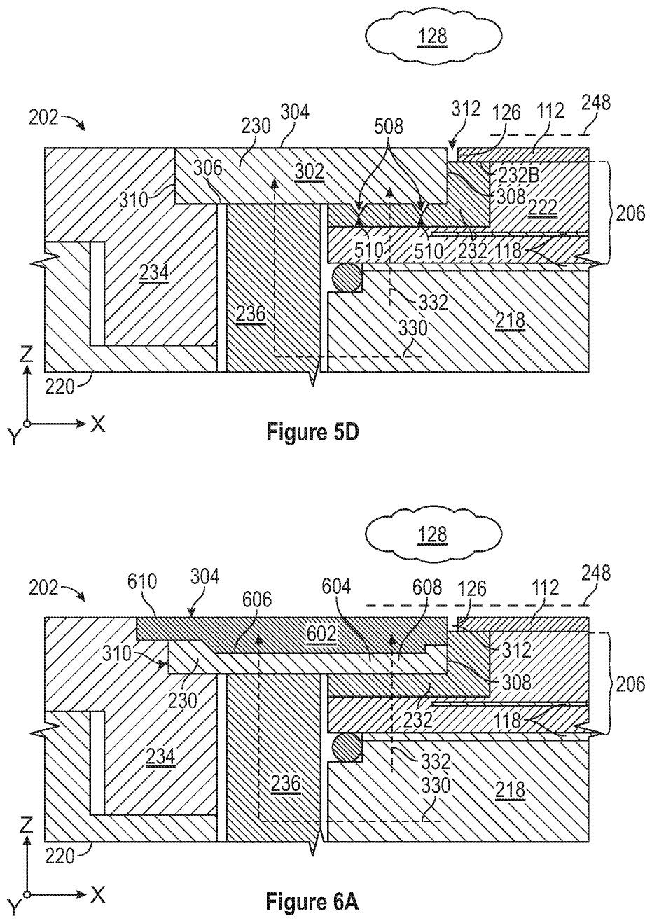

In some embodiments, as shown in FIGS. 5A, 5B, 5C, and 5C, the bottom surface 306 of the edge ring 230 and the top surface 336 of the support ring 232 are patterned such that the bottom surface 306 contours the top surface 336 for precise alignment and lateral position control of the edge ring 230 relative to the support ring 232 and electrostatic chuck 206. In FIGS. 5A and 5B, the bottom surface 306 of the edge ring 230 includes one or more depressions 504 that align with one or more protrusions 506 formed in the support ring 232. The depressions 504 and the edges of the protrusions 506 may be substantially parallel to the Z-direction as shown in FIG. 5A, or may be at an angle to the Z-direction as shown in FIGS. 5B and 5C. In FIG. 5C, one of the depressions 504 is coincident with the inner surface 308 of the edge ring 230. In FIG. 5D, the bottom surface 306 of the edge ring 230 includes one or more bumps 508 that interlock with one or more features 510 formed on the top surface 336 of the support ring 232.

In addition to precise alignment of the edge ring 230 and the support ring 232, the patterned surfaces of the edge ring 230 and the support ring 232 may be used to adjust the capacitive coupling between the edge ring 230 and the cooling plate 218, thus altering the plasma sheath 248 at the outer surface of the edge ring 230, and thus altering the plasma sheath 248 near the outer edge 126 of the substrate 112. Due to the support ring's 232 position relative to the RF biased electrode 118 versus the edge ring's 230 position to the RF biased electrode 118, it is believed that the capacitive coupling path 332 to the plasma 128 through the protrusions 506 will have a greater capacitive coupling than the capacitive coupling in the regions formed between the protrusions 506. Therefore, the structure of the protrusions 506 can be used to adjust and/or control the shape of the plasma sheath 248. In some configurations, the structure of the protrusions 506 can include their lateral position (e.g., radial position) relative to the edge of the substrate 112 and/or the relative height (Z-direction) of the protrusions 506.

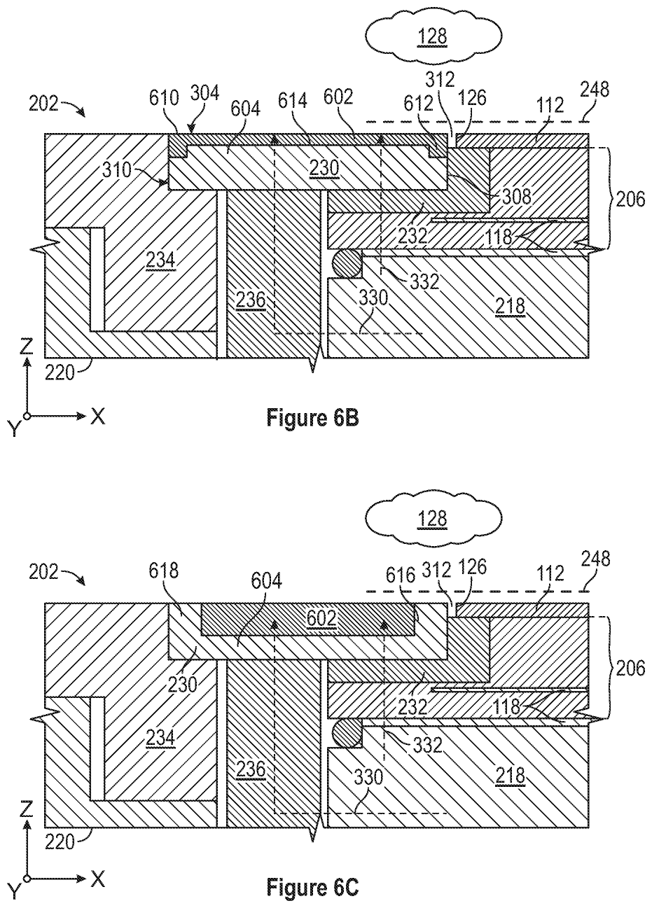

In other embodiments, such as that shown in FIG. 6A, 6B, and 6C, the edge ring 230 may comprise a stack of an upper edge ring 602 and a middle edge ring 604. The upper edge ring 602 may be consumable and the middle edge ring 604 may be non-consumable. Specifically, after the upper edge ring 602 is exposed to plasma during multiple plasma etching processes or for pre-defined time duration, the upper edge ring 602 can be removed from the middle edge ring 604 and replaced with a new upper edge ring 602 for a proceeding plasma etching process. The middle edge ring 604 is not directly exposed to plasma, and can be cleaned and reused for the proceeding plasma etching process. The upper edge ring 602 may be fabricated from a plasma resistant material such as silicon, silicon carbide (SiC), or other suitable material. In some embodiments, the middle edge ring 604 may be fabricated from or contain a conductive material such aluminum and aluminum alloy. In some other embodiments, the middle edge ring 604 may be fabricated from a plasma resistant material such as silicon, silicon carbide (SiC), or quartz, for reducing a cost of fabricating the middle edge ring 604.

In FIG. 6A, the upper edge ring 602 includes a lower interlocking coupling (e.g., a protrusion) 606 on a bottom surface of the upper edge ring 602 and the middle edge ring 604 has an upper interlocking coupling (e.g., a depression 608) formed on a top surface of the middle edge ring 604 between the inner surface 308 and the outer surface 310. The protrusion 606 and the depression 608 at least partially extend along a direction (e.g., Z-direction parallel to the central axis of the edge ring 230) that is at an angle to the top surface 304 of the edge ring 230 (e.g.,) 90°. The lower interlocking coupling (the protrusion) 606 engages with the upper interlocking coupling (the depression) 408 when the upper edge ring 602 and the middle edge ring 604 are stacked. When the upper edge ring 602 is removed from the middle edge ring 604, the lower interlocking coupling (the protrusion) 606 disengages from the upper interlocking coupling (the depression) 408. In some embodiments, the protrusion 606 and the depression 608 have inner and outer surfaces that are slanted with respect to the inner surface 308 and the outer surface 310 of the edge ring 230. In some embodiments, the protrusion 606 and the depression 608 have inner and outer surface substantially parallel to the Z-direction. The upper edge ring 602 protects the middle edge ring 604 from being exposed to plasma during a plasma etching process, and the protrusion 606 and depression 608 together prevent lateral movement between upper edge ring 602 and the middle edge ring 604. The upper edge ring 602 may also have an extended step 412 extending radially-outward from the outer surface 310 and into the cover ring 234 (i.e., the upper edge ring 602 extends radially-outward more into the cover ring 234 more than the middle edge ring 604). The extended step 412 is used to further extend the outer surface of the upper edge ring 602 and thus the outer surface of the plasma sheath 248 a further distance from the outer surface of the substrate 112. As will be discussed further below, the thickness of protrusion 606 within the upper edge ring 602 and the thickness of the depression 608 of the middle edge ring 604, both measured in Z-direction, affects the capacitive coupling of each of the parts to the plasma 128 which will affect the shape of the plasma sheath formed over these parts.

In FIG. 6B, the upper edge ring 602 includes a lower interlocking coupling (e.g., a depression) 414 on the bottom surface of the upper edge ring 602 and the middle edge ring 604 has an upper interlocking coupling (e.g. a protrusion) 614 formed on the top surface of the middle edge ring 604 between the inner surface 308 and the outer surface 310. The depression 414 and the protrusion 614 extend partially along a direction that is at an angle to the top surface 304 of the edge ring 230. The lower interlocking coupling (the depression) 414 engages with the upper interlocking coupling (the protrusion) 614 when the upper edge ring 602 and the middle edge ring 604 are stacked. When the upper edge ring 602 is removed from the middle edge ring 604, the lower interlocking coupling (the depression) 414 disengages from the upper interlocking coupling (the protrusion) 614. In some embodiments, the depression 414 and the protrusion 614 have inner and outer surfaces slanted with respect to the inner surface 308 and the outer surface 310 of the edge ring 230. In some embodiments, the depression 414 and the protrusion 614 have inner and outer surfaces substantially parallel to the Z-direction. The upper edge ring 602 protects the middle edge ring 604 from being exposed to plasma during a plasma etching process. In some embodiments, an upper edge ring 602 that has a thin cross-section, as shown in FIG. 6B, versus a thick cross-section, as shown in FIG. 4A, has advantages due to an improved capacitive coupling of the upper edge ring 602 and middle edge ring 604 combination (i.e., edge ring 230) to the plasma 128. It is believed that the improved capacitive coupling can be achieved due to the smaller voltage drop created across the upper edge ring 602 due to its thickness, assuming that the middle edge ring 604 achieves the same bias voltage in each of the configurations shown in FIGS. 6A and 6B. In some configurations, the ratio of thicknesses of the upper edge ring 602 to thickness of the middle edge ring 604, as measured in the Z-direction, is between about 0.1 and 0.5.

In FIG. 6C, the middle edge ring 604 has a side portion 616 on the inner surface 308. The side portion 616 extends partially along a direction that is at an angle to the top surface 304 of the edge ring 230. The side portion 616 provides a greater capacitive coupling between the edge ring 230 and the cooling plate 218 via the support ring 232. The middle edge ring 604 may have another side portion 618 on the outer surface 310 extending partially along a direction that is at an angle to the top surface 304 of the edge ring 230. The upper edge ring 602 is enclosed between the side portions 616 and 618. A change in the capacitive coupling changes the power coupled between the edge ring 230 and the cooling plate 218 and therefore the voltage that is applied to the edge ring 230. Controlling the voltage applied to the edge ring 230 allows for controlling plasma sheath 248 profile at the outer edge 126 of the substrate to compensate for non-uniformity.

It should be noted that the particular process kit configuration examples described above are just some possible examples of an upper edge ring and a middle edge ring according to the present disclosure and do not limit the possible configurations, specifications, or the like of the upper edge ring and the middle edge ring according to the present disclosure. For example, shapes or sizes of the upper edge ring and the middle edge ring are not limited to the examples described above.

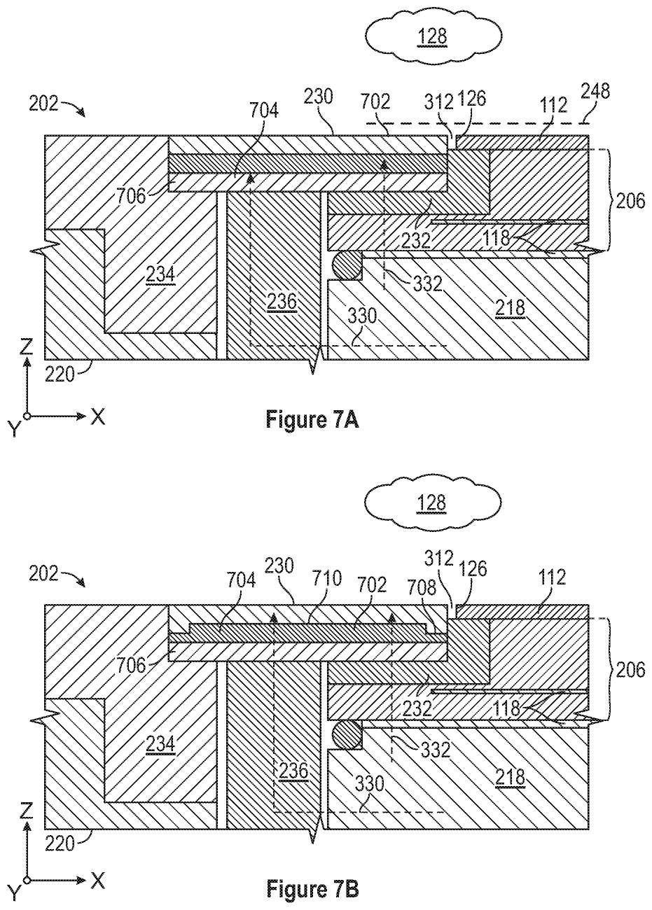

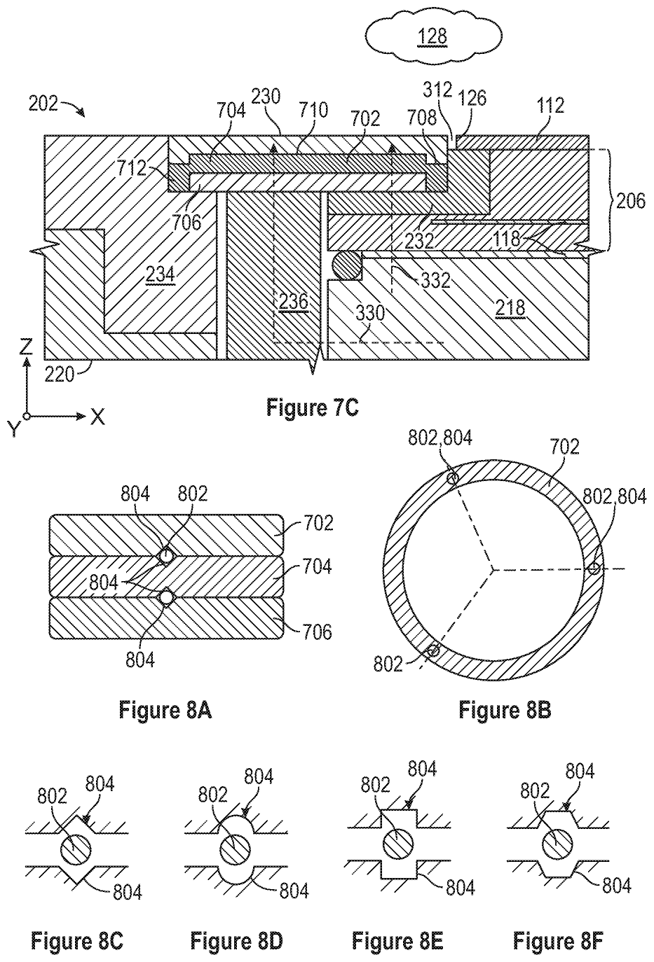

In other embodiments, such as that shown in FIGS. 7A, 7B, and 7C, the edge ring 230 may comprise a stack of an upper edge ring 702, a middle edge ring 704, and a lower edge ring 706. The upper edge ring 702 may be consumable and the middle edge ring 704 and the lower edge ring 706 may be non-consumable. Specifically, after the upper edge ring 702 is exposed to plasma during multiple plasma etching processes or for pre-defined time duration, the upper edge ring 702 can be removed from the middle edge ring 704 and replaced with a new upper edge ring 702 for a proceeding plasma etching process. The middle edge ring 704 and the lower edge ring 706 are not directly exposed to plasma, and can be cleaned and reused for the proceeding plasma etching. The middle edge ring 704 may also be removed from the lower edge ring 706 for replacement. The upper edge ring 702 may be fabricated from a plasma resistant material such as silicon, silicon carbide (SiC), or other suitable material. In some embodiments, the middle edge ring 704 and the lower edge ring 706 may be fabricated from or contain a conductive material such as aluminum and aluminum alloy. In some other embodiments, the middle edge ring 704 and the lower edge ring 706 may be fabricated from a plasma resistant material such as silicon, silicon carbide (SiC) or quartz, for reducing a cost of fabricating the edge ring 230. It should be noted that the particular process kit configuration examples described above are just some possible examples of a stack of an upper edge ring, a middle edge ring, and a lower edge ring according to the present disclosure and do not limit the possible configurations, specifications, or the like of an upper edge ring, a middle edge ring, and a lower edge ring according to the present disclosure. For example, shapes, sizes, or materials of the upper edge ring and the middle edge ring are not limited to the particular examples described above. For example, in FIG. 7A, the upper edge ring 702, the middle edge ring 704, and the lower edge ring 706 may have annular bodies that may require simple fabrication processes.

In FIG. 7B, the upper edge ring 702 may have a depression 708 and the middle edge ring 704 may have a protrusion 710 between the inner surface 308 and the outer surface 310. The depression 708 and the protrusion 710 interlock when the upper edge ring 702 and the middle edge ring 704 are stack. In FIG. 7C, the middle edge ring 704 may have side portions 712 on the inner surface 308 and the outer surface 310 to cover a top surface and side surfaces of the lower edge ring 706, and protect the middle edge ring 704 from being exposed to plasma during a plasma etching process.

FIGS. 8A and 8B show a side view (along the Z direction) and a cross-sectional view (in the X-Y plane) of the edge ring 230 that includes the upper edge ring 702, the middle edge ring 704, and the lower edge ring 706. In some embodiments, the upper edge ring 702, the middle edge ring 704, and the lower edge ring 706 are aligned and secured via one or more alignment spheres 802. In some embodiments, a bottom surface of the upper edge ring 702, a top surface and a bottom surface of the middle edge ring 704, and a top surface of the lower edge ring 706 each have one or more indents 804 that are radially 120° apart from each other. The alignment spheres 802 may be each positioned within a space formed between, and bonded or glued to, opposing indents 804 of a pair of contacting surfaces (i.e., the bottom surface of the upper edge ring 702 and the top surface of the middle edge ring 704, and the bottom surface of the middle edge ring 704 and the top surface of the lower edge ring 706). The alignment spheres 802 may be fabricated from quartz. It should be noted that the particular configuration examples of the edge ring 230 described above are just some possible examples of alignment of a stack of an upper edge ring, a middle edge ring, and a lower edge ring according to the present disclosure and do not limit the possible configurations, specifications, or the like of the edge ring 230. The alignment spheres 802 may be used for alignment of a stack of an upper edge ring and a middle edge ring only, for example, the upper edge ring 602 and the middle edge ring 605, and for a stack of an upper edge ring, a middle ring, and a lower edge ring having configurations different from the examples described above.

FIGS. 8C, 8D, 8E, and 8F illustrate examples of shapes of the indents 804 that may be used with the alignment spheres 802. In FIG. 8C, the indents 804 are cone shaped. In FIG. 8C, the indents 804 are spherically shaped. In FIG. 8E, the indents 804 are square or rectangular shaped. In FIG. 8F, the indents 804 are rhombus shaped. It should be noted that the particular example shapes of the indents 804 described above are just some possible examples according to the present disclosure and do not limit the possible configurations, specifications, or the like of the indents.

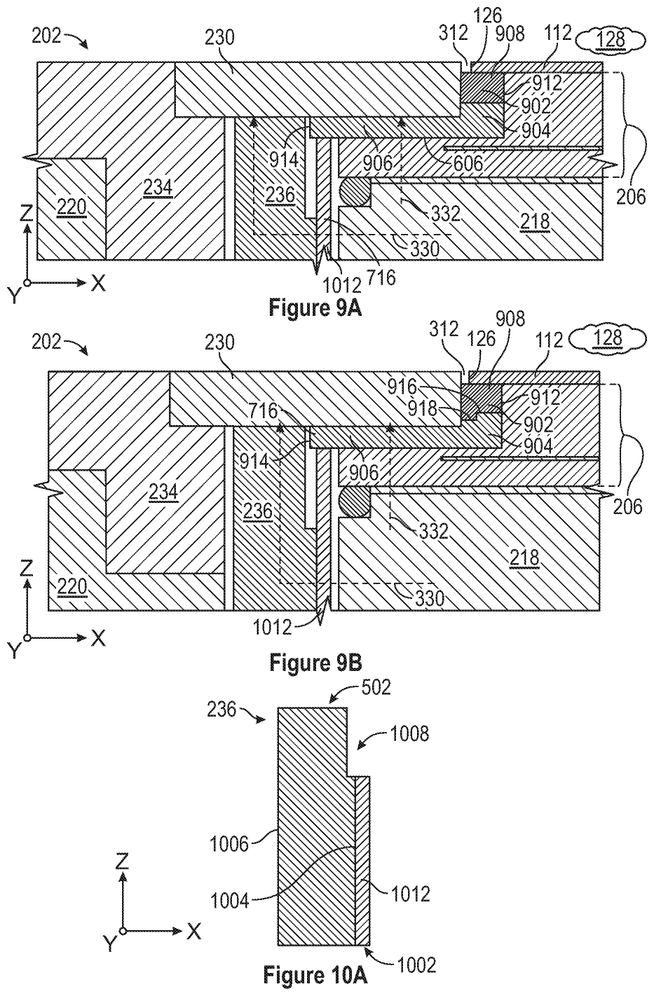

As discussed above, some embodiments of the process kit 202 include a support ring 232 that is disposed at and/or underneath the outer edge of a substrate 112 during processing, and is configured to help alter the capacitive coupling of achieved by each of the process kit components due to its shape and material properties. Referring to FIG. 3B, for example, the support ring 232 generally includes an annular body 334 having a central axis in the Z-direction. The annular body 334 has a top surface 336, a bottom surface 338, an inner surface 340, and an outer surface 342. At least a portion of the inner surface 340 between the top surface 336 and the bottom surface 338 has a diameter that is greater than the diameter of the substrate 112. In one embodiment of the disclosure, as shown in FIG. 9A, the support ring 232 includes two separate parts, such as an upper support ring 902 and a lower support ring 904.

FIG. 9A is a schematic partial cross-sectional view of the process kit 202. The support ring 232, as shown in FIG. 9A, includes an upper support ring 902 and a lower support ring 904 that are stacked on top of each other. The support ring 232 includes an annular body 906 and having a central axis in the Z-direction. The annular body 906 has a top surface 908, a bottom surface 910, an inner surface 912, and an outer surface 914. The support ring 232 is configured to support the edge ring 230 in the process chamber 100. For example, the support ring 232 supports the edge ring 230 from the bottom surface 242 of the edge ring 230. The upper support ring 902 may be consumable and the lower support ring 904 may be non-consumable. Specifically, after the upper support ring 902 is exposed to plasma during multiple plasma etching processes or for pre-defined time duration, the upper support ring 902 may be removed from the lower support ring 904 and replaced with a new upper support ring 902. The lower support ring 904 is not directly exposed to plasma, and can be cleaned and reused for the proceeding plasma etching process. The upper support ring 902 may fabricated from a plasma resistive material such as silicon and silicon carbide (SiC) for protection against a direct exposure to plasma. The lower support ring 904 may be fabricated from a material such as quartz, aluminum, and aluminum alloy for reducing a cost of fabricating the support ring 232. In some embodiments, after the top surface 908 of the upper support ring 902 has been exposed to plasma during multiple plasma etching processes or for pre-defined time duration, the upper support ring 902 may be flipped and the bottom surface 910 of the upper support ring 902 may be used for protection from plasma in the proceeding plasma etching process.

In other embodiments, such as that shown in FIG. 9B, the upper support ring 902 has a protrusion 916 extending partially along the height of the support ring 232 towards the bottom surface 910. The lower support ring 904 may have a depression 918. The protrusion 916 and the depression 918 are located between the inner surface 912 and the outer surface 914 and interlock when the upper support ring 902 and the lower support ring 904 are stacked. The upper support ring 902 may be securely disposed on the lower support ring 904 by the interlocking. Due to a shape of the upper support ring 902 shown in FIG. 9B, the support ring 232 may not be flipped to use the bottom surface 910 for protection from plasma in the proceeding plasma etching process after the top surface 908 of the upper support ring 902 has been exposed to plasma during multiple plasma etching processes or for pre-defined time duration.

Referring back to FIGS. 2A and 2B, power may be coupled from the cooling plate 218 to the edge ring 230 along two paths represented by the two capacitive coupling paths 330, 332. The amount of power coupled to the plasma 128 depends on the coupling via the capacitive coupling paths 330, 332. The amount of capacitive coupling created along the capacitive coupling path 332 is fixed due to the stack-up of parts that will remain present and unchanged throughout most of the life of the substrate support assembly 110. The amount of capacitive coupling created along the capacitive coupling path 330 can vary, due to the erosion of the edge ring 230 during processing and also can be separately controlled by the process of repositioning of the edge ring 230 relative the substrate 112. For example, the capacitive coupling path 330 can be tuned by moving the movable ring 236 under the edge ring 230 vertically, thus modifying a vertical gap 254 (illustrated in FIG. 2B) formed between the edge ring 230 and the support ring 232. Controlling the vertical gap 254 controls the capacitive coupling created along the capacitive coupling path 330. As the vertical gap 254 decreases, the capacitive coupling created along the capacitive coupling path 330 increases, and thus a voltage applied to the edge ring 230 increases. As the vertical gap 254 increases, i.e., as the movable ring 236 is moved farther away from the edge ring 230, the capacitive coupling created along the capacitive coupling path 330 decreases, which leads to a decrease of the voltage applied to the edge ring 230. As such, controlling a size or a shape of the vertical gap 254 alters the amount of capacitive coupling that follows the capacitive coupling path 330 between the edge ring 230 and the cooling plate 218, thus changes the voltage that is applied to the edge ring 230. Controlling the voltage applied to the edge ring 230 allows for control of a plasma sheath above the substrate 112 and the edge ring 230.

It should be noted that the particular process kit configuration examples described above are just some possible examples of interlocking of a protrusion of an upper support ring and a lower support ring according to the present disclosure and do not limit the possible configurations, specifications, or the like of the upper support ring and the lower support ring according to the present disclosure. For example, shapes, sizes, or locations of the protrusion and the depression are not limited to the examples described above.

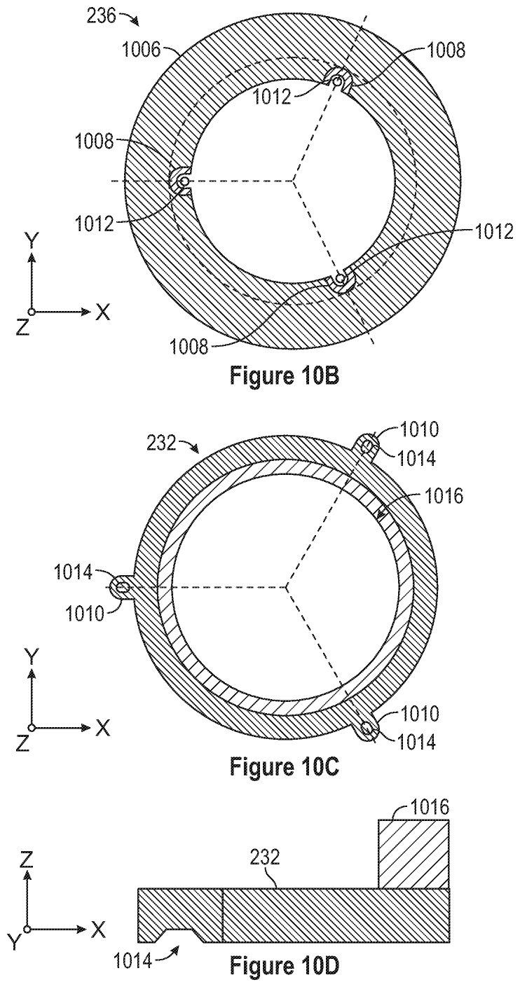

FIGS. 10A and 10B are a side cross-sectional view and a top view of the movable ring 236. FIG. 10C is a top view of the support ring 232. The movable ring 236 has the top surface 502, a bottom surface 1002, an inner surface 1004, and an outer edge 1006. The movable ring 236 may be fabricated from a conductive material, such as aluminum, yttria (Yttrium oxide, Y₂O₃), or any plasma resistant material. In one embodiment, the movable ring 236 may move in an opening formed in each of the insulating plate 214 and the ground plate 212 and the outer edge 1006 may be positioned adjacent to inner walls of the opening. The movable ring 236 is disposed beneath the edge ring 230. The movable ring 236 may be operably coupled with the actuating mechanism 252 that can raise or lower the movable ring 236. For example, in one embodiment, the movable ring 236 extends down past the electrostatic chuck 206, alongside the cooling plate 218. In one embodiment, the movable ring 236 has a height that extends all the way to the bottom of the cooling plate 218. As such, the movable ring 236 is able to couple power from the cooling plate 218 to the edge ring 230.

The movable ring 236 may have one or more notches 1008 on the inner surface 1004. Each notch 1008 is a U-shaped slot opening on the inner surface 1004, and laterally extending radially-outward from the inner surface 1004 towards the outer edge 1006 and vertically a depth extending from the top surface 502 towards the bottom surface 1002. The support ring 232 may include one or more portions (referred to as “ears”) 1010 laterally protruding radially-outward from the outer surface 914. The notches 1008 formed on the inner surface 1004 of the movable ring 236 are configured to house the ears 1010 of the support ring 232 so that the support ring 232 can move freely relative to the movable ring 236 in the Z-direction. One or more lift pins 1012 interfaces with or are disposed adjacent to the movable ring 236 and engage with blind recesses 1014 formed in the ears 1010 of the support ring 232. In FIG. 10B, three lift pins 1012 that are radially 120° apart from each other are shown, and are positioned to interface with the blind recesses 1014 (FIGS. 10C-10D) formed in the ears 1010 of support ring 232.

FIG. 10D is a cross-sectional view of the support ring 232 according to one embodiment of the disclosure provided herein. In some embodiments, as shown in FIGS. 10C and 10D, one or more top support rings 1016 may be placed on a top surface of the support ring 232 at the inner surface 1004 to form a support ring 232 that is similarly configured as the support rings 232 shown in FIGS. 9A-9B. As similarly discussed in FIG. 9A regarding the upper support ring 902, the top support rings 1016 can be used to protect the support ring 232 ring from being exposed to the plasma. The top support rings 1016 may be fabricated from a material such as silicon and silicon carbide (SiC). In some embodiments, the support ring 232 and one or more top support rings 1016 are integrated.

FIG. 11 is a schematic cross-sectional view of a combined system 1100 including the process kit 202, a lift mechanism 1102, and an actuating mechanism 252. The actuating mechanism 252 may raise and lower the movable ring 236.

The lift mechanism 1102 includes one or more actuators 1104 (one is shown), such as a servo motor, one or more pin holders 1106 (one is shown), one or more bellows 1108 (one is shown), and the one or more lift pins 1012 (one is shown). The lift pins 1012 may be fabricated from quartz, sapphire, or other suitable material. Each pin holder 1106 is coupled to a corresponding actuator 1104, each bellows 1108 surrounds a corresponding pin holder 1106, and each lift pin 1012 is supported by a corresponding pin holder 1106. Each lift pin 1012 is positioned alongside the movable ring 236 through an opening formed in each of the ground plate 212 and the insulating plate 214. One or more push pin guides (not shown) may be positioned around the openings in the ground plate 212 and the insulating plate 214. The one or more actuators 1104 can raise the one or more pin holders 1106 and the one or more lift pins 1012, which in turn raise or tilt the edge ring 230.

The actuating mechanism 252 includes one or more actuators 1110 (one is shown), such as a servo motor, one or more pin holders 1112 (one is shown), one or more bellows 1114 (one is shown), and the one or more lift pins 1116 (one is shown). The lift pins 1116 may be fabricated from quartz, sapphire, or other suitable material. Each pin holder 1112 is coupled to a corresponding actuator 1110, each bellows 1114 surrounds a corresponding pin holder 1112, and each lift pin 1116 is supported by a corresponding pin holder 1112. Each lift pin 1116 is in contact with the movable ring 236. The one or more actuators 1110 can raise the one or more pin holders 1112 and the one or more lift pins 1116, which in turn raise or lower the movable ring 236.

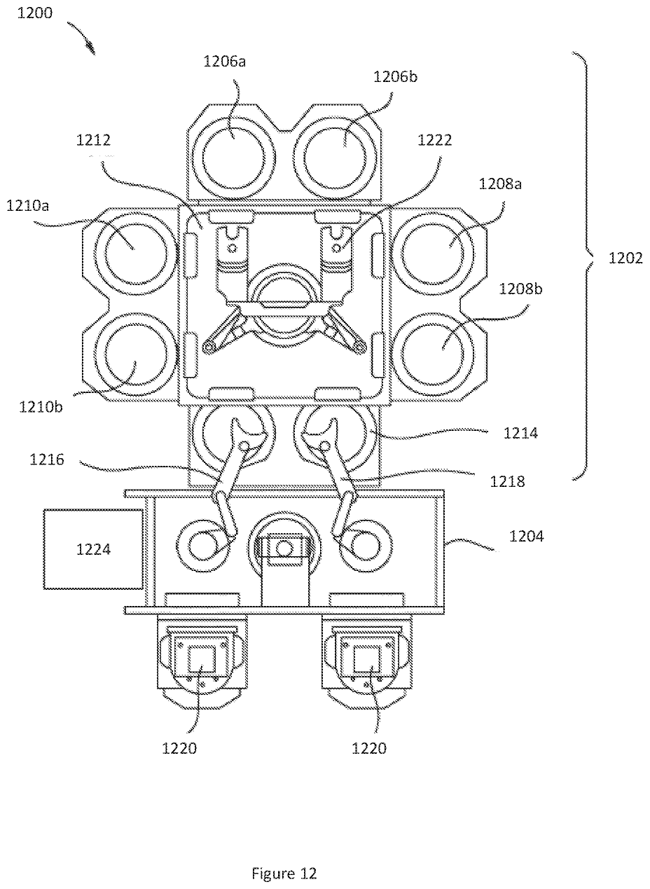

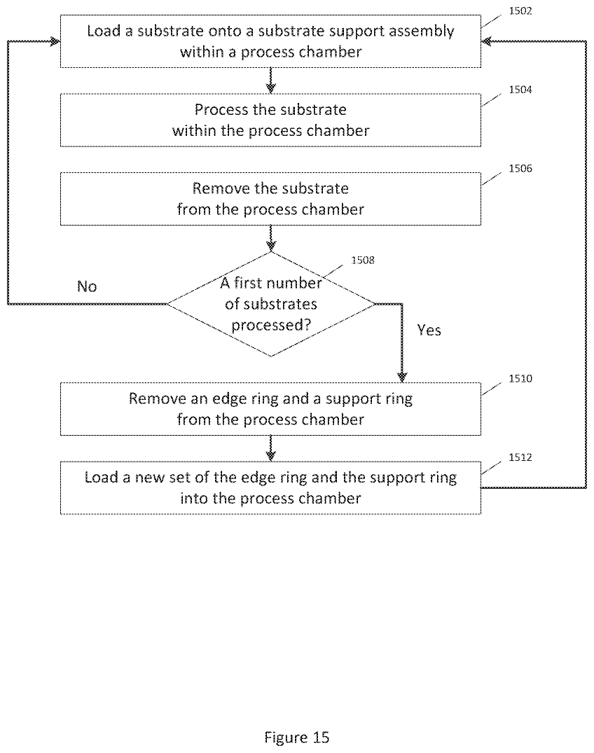

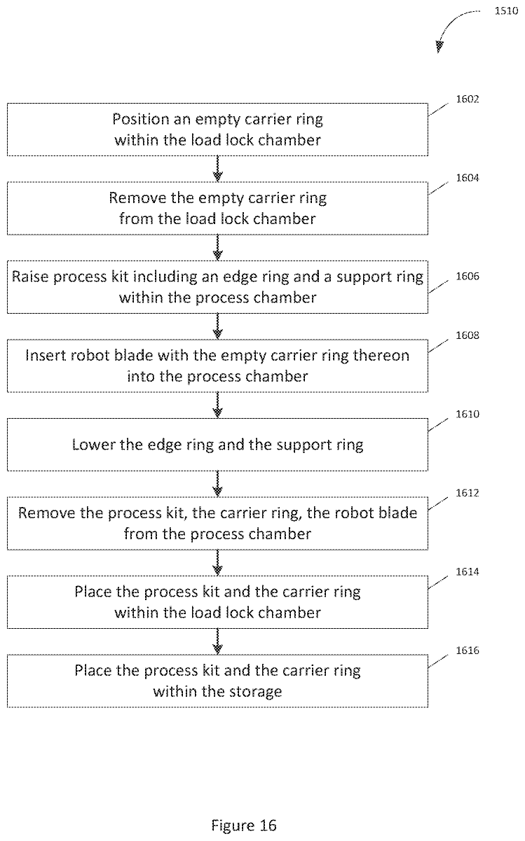

FIG. 12 is a schematic top view of a processing system 1200 that can be used to perform the processing sequences illustrated in FIGS. 15 and 16 in accordance with implementations of the present disclosure. One example of the processing system 1200 is the PRODUCER® or CENTRIS™ system available from Applied Materials, Inc., of Santa Clara, Calif. The processing system 1200 includes a vacuum-tight processing platform 1202 and a factory interface 1204. The processing platform 1202 includes a plurality of process chambers 1206a-b, 1208a-b, 1210a-b coupled to a vacuum substrate transfer chamber 1212, and a load lock chamber 1214 that is disposed between and coupled to the vacuum substrate transfer chamber 1212 and the factory interface 1204.

The factory interface 1204 includes at least one factory interface robot 1216, 1218 to facilitate transfer of substrates. Each of the factory interface robots 1216, 1218 includes a robot wrist 1304 and a robot blade 1306. The factory interface 1204 is configured to accept one or more front opening unified pod (FOUP) 1220. In one example, three FOUPs are configured to engage the factory interface 1204. The factory interface robots 1216, 1218 transfer the substrates (e.g., the substrate 112) from the factory interface 1204 to the processing platform 1202 where at least one transfer robot 1222 receives the substrates from the factory interface robots 1216, 1218 and then transfers them to any of the process chambers 1206a-b, 1208a-b, 1210a-b. In one implementation, the process chambers 1206a-b are process chambers that may be used to perform plasma-assisted processes in block 1504. Once the processes are completed, the substrates are transferred by the transfer robot 1222 to the load lock chamber 1214. The transfer robot 1222 includes the robot wrist 1304 and the robot blade 1306. The factory interface robot 1216, 1218 then pick up the substrates from the load lock chamber 1214 and transports them back to the FOUPs 1220. One or more set of the edge ring 230 and the support ring 232 may be stored in a storage chamber 1224.

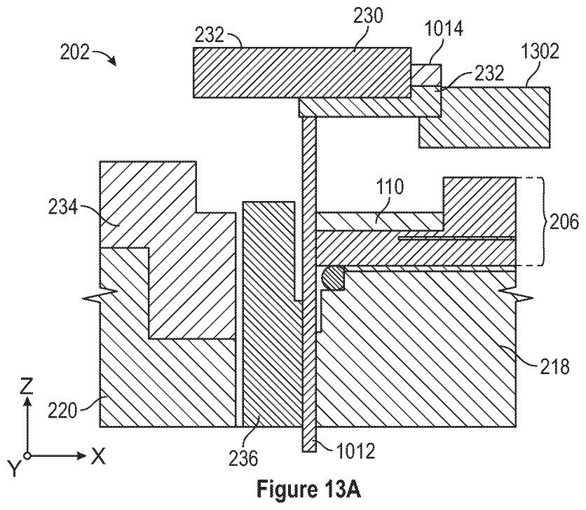

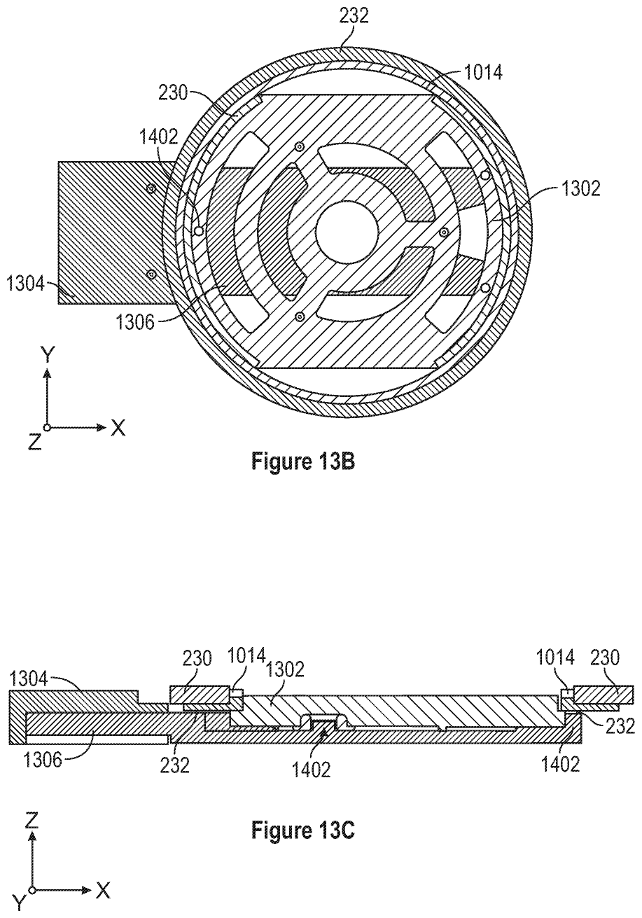

FIG. 13A is a schematic cross-sectional view of the process kit 202 in a raised position. FIGS. 13B and 13C are a schematic top view and a cross-sectional view of the process kit 202 held by a carrier ring 1302 and disposed at least partially on the top surface of the carrier ring 1302. The edge ring 230 is placed on the support ring 232. A robot wrist 1304 and a robot blade 1306 of the transfer robot 1222 (not shown in FIG. 13B) are positioned underneath the carrier ring 1302 to support the carrier ring 1302 and the process kit 202. The robot wrist 1304 moves the robot blade 1306 both laterally and rotationally to retrieve, transfer, and deliver the process kit 202 including the edge ring 230 and the support ring 232 from one location to another within the processing system 1200. When the support ring 232 and/or the edge ring 230 are to be positioned within or replaced from the process chamber 100, the robot wrist 1304 moves the robot blade 1306 to the entry ports 148 on the chamber body 102, through which the support ring 232 and/or the edge ring 230 are to be positioned within and removed from the process chamber 100 without venting the process chamber 100. Once the used support ring 232 and/or the edge ring 230 are removed from the process chamber 100 by the transfer robot 1222, one or more hardware devices are used to unload the support ring 232 and/or the edge ring 230 from the carrier ring 1302, replaced with a new support ring 232 and/or an edge ring 230, loaded on the carrier ring 1302, and transferred back into the process chamber 100 by the robot blade 1306 through the entry ports 148.

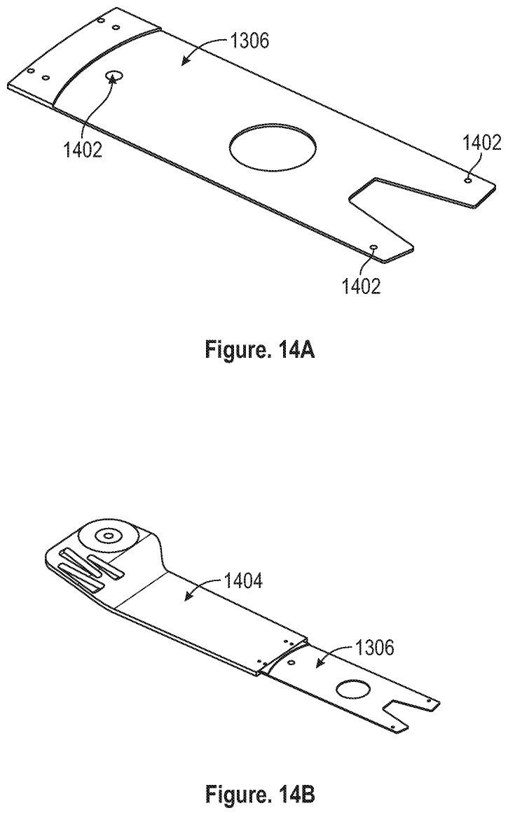

FIG. 14A is a schematic view of the robot blade 1306. In some embodiments, the robot blade 1306 includes one or more pads 1402 that may be used to protect the substrate 112 from touching portions of the robot blade 1306 that are in contact with the carrier ring 1302 when loading and transferring a substrate 112 on the robot blade 1306. The vertical edges of the pads 1402 may be also use for alignment with the carrier ring 1302. The robot blade 1306 may be supported by a robot wrist adapter 1404, as shown in FIG. 14B.

FIG. 15 is a flowchart of a method 1500 according to examples described herein. FIG. 15 will be discussed in conjunction with FIGS. 1, 2, 6A, 6B, 6C, 7A, 7B, 7C, 9A, 9B, and 11 to further describe the processes for processing substrates in the process chamber 100.

The method 1500 starts at block 1502 by loading a semiconductor substrate, such as the substrate 112 shown in FIG. 1, via one of the entry ports 148 onto the substrate support assembly 110 disposed within the process volume 106 of the process chamber 100, as shown in FIG. 1. The substrate support assembly 110 includes the process kit 202 that surrounds the outer edge 126 of the substrate 112. The process kit 202 includes the edge ring 230 and the support ring 232. Suitable process chamber may include an inductively coupled plasma etch chamber, or the like. Exemplary etching chamber that may be adapted for silicon etching include CENTRIS™ SYM3™ system or Producer® Etch system, both are available from Applied Materials, Inc., of Santa Clara, Calif. It is contemplated that other suitable plasma process chambers, including those from other manufacturers, may also be utilized.

In block 1504, the substrate 112 disposed on the substrate support assembly 110 is processed within the process volume 106 of the process chamber 100. During the processing of the substrate 112, a portion of the substrate support 204 and the top surface 304 of the edge ring 230 can be, for example, coplanar with the top surface 250 of the substrate 112, as shown in FIG. 11. A position of the movable ring 236, and thus the position of the edge ring 230, is adjusted relative to the surface of the substrate 112 by the actuating mechanism 252 such that the plasma sheath 248 formed during plasma processing has a desired shape. In one example, the shape of the plasma sheath 248 has as parallel and/or flat profile across the edge region and/or all portions of the top surface 250 of the substrate 112. The support ring 232 may comprise the upper support ring 902 and the lower support ring 904 as shown in FIGS. 9A and 9B. The edge ring 230 may comprise the upper edge ring 602 and the middle edge ring 604 as shown in FIGS. 6A, 6B, and 6C, or the upper edge ring 702, the middle edge ring 704, and the lower edge ring 706 as shown in FIGS. 7A, 7B, and 7C.

After processing the substrate 112, in block 1506, the substrate 112 is elevated by a substrate lift pin (not shown), which is controlled by a substrate lift servo motor (not shown), and removed from the process volume 106 of the process chamber 100 by robot blade 1306 via the entry port 148.

In block 1508, it is determined whether or not a first number of substrates (e.g., 10, 1000 or even 10,000 substrates) have been processed within the process volume 106 of the process chamber 100. If it is determined in block 1508 that “no” the number has not been reached (i.e. less than the first number of substrates have been processed), the process then returns to block 1502 so that another substrate 112 can be processed within the process chamber 100. If it is determined in block 1508 that “yes” the number has been reached (i.e. the first number of substrates have been processed), in block 1510, the edge ring 230 and the support ring 232 are removed from the process volume 106 of the process chamber 100 via the entry port 148 without venting the process chamber 100 and transferred to the storage 1224 (FIG. 12). The processes performed in block 1510 include at least blocks 1602-1616, which are shown in FIG. 16.

FIG. 16 is a flow chart of various method steps performed in block 1510 according to examples described herein. FIG. 16 will be discussed in conjunction with FIGS. 6A, 6B, 6C, 7A, 7B, 7C, 9A, 9B, 11, 12, 13A to further describe the processes for removing the process kit from the process volume 106 of the process chamber 100 and storing the process kit in the storage 1224. The method may be stored on and executed by a controller, such as the controller 116.

In block 1602, a factory interface robot 1216, 1218, which typically within an atmospheric pressure environment, positions an empty carrier ring 1302 within the load lock chamber 1214. During this step, the factory interface robot 1216, 1218 will remove the empty carrier ring 1302, which is positioned on a shelf (not shown) of a plurality of vertically spaced shelves (not shown) that are positioned within the storage chamber 1224, and then deposit the empty carrier ring 1302 onto a support (not shown) positioned within the load lock chamber 1214.

In block 1604, the transfer robot 1222 picks up the empty carrier ring 1302, such that the empty carrier ring 1302 is positioned onto a robot blade 1306 (FIG. 13) coupled to the transfer robot 1222, and then removes the empty carrier ring 1302 from the load lock chamber 1214. During block 1602 or block 1604, or even in between blocks 1602 and 1604, the load lock chamber 1214 is pumped down to a vacuum pressure that matches the pressure within the vacuum substrate transfer chamber 1212 in which the transfer robot 1222 is disposed. The equalization of pressure between the load lock chamber 1214 and the vacuum substrate transfer chamber 1212 allows the transfer robot 1222 to access the load lock chamber 1214 without causing a rush of gas, which can dislodge the carrier ring 1302 from the robot blade 1306, and possibly allow contaminants to flow into the vacuum substrate transfer chamber 1212 from the load lock chamber 1214 as a separating slit valve (not shown) is opened.

In block 1606, the process kit 202 including the edge ring 230 and the support ring 232 is raised by the lift pins 1012, and their associated actuator 1104, to a raised position within the process volume 106 of the process chamber 100. The raised position, as illustrated in FIG. 13A, is a distance above the top surface of the electrostatic chuck 206 of the substrate support 204.

In block 1608, the transfer robot 1222 inserts the robot blade 1306, with the empty carrier ring 1302 disposed thereon, into the process volume 106 of the process chamber 100 via the entry port 148. In block 1608, the transfer robot 1222 moves the robot blade 1306 with the empty carrier ring 1302 underneath the process kit 202.

In block 1610, lift pins 1012, and their associated actuator 1104, lower the edge ring 230 and the support ring 232 so that they are positioned on the carrier ring 1302. The carrier ring 1302 and robot blade 1306 thus fully support the used edge ring 230 and the support ring 232.

In block 1612, the transfer robot 1222 removes the robot blade 1306, the carrier ring 1302, and the process kit 202 from the process volume 106 of the process chamber 100 via the entry port 148.

In block 1614, the transfer robot 1222 places the carrier ring 1302 and the process kit 202 on the support (not shown) positioned within the load lock chamber 1214. During block 1614, one or more devices are used to unmount the carrier ring 1302 and the process kit 202 from the robot blade 1306, and the robot blade 1306 is retracted from the load lock chamber 1214. During block 1614, or after block 1614 is performed, the load lock chamber 1214 is vented to an atmospheric pressure or a pressure that matches the pressure in the environment in which the factory interface robot 1216, 1218 is disposed.

In block 1616, the factory interface robot 1216, 1218 transfers the process kit 202 and the carrier ring 1302 to one of the shelves positioned within the storage 1224. The consumable parts of the edge ring 230 and the support ring 232 stored in the storage 1224, such as the upper edge ring 602, the upper edge ring 702, and the middle edge ring 704, which have been eroded during the processing of the first number of substrates, can be removed from the storage 1224 by a user. In some cases, the used edge ring 230 and/or the support ring 232 are removed from the carrier ring 1302 and are replaced with a new edge ring 230 and/or the support ring 232.

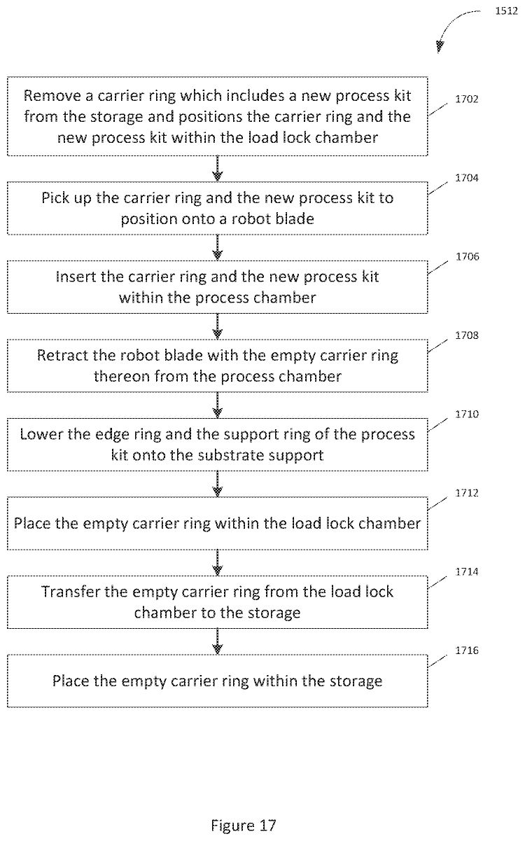

In block 1512, a new set of the edge ring 230 and/or the support ring 232 are loaded into the process volume 106 of the process chamber 100 and the process returns to block 1502. The processes performed in block 1512 include blocks 1702-1716 as shown in FIG. 17.

FIG. 17 is a flow chart of a method used to perform the processes found in block 1512, according to examples described herein. FIG. 17 will be discussed in conjunction with FIGS. 6A, 6B, 6C, 7A, 7B, 7C, 9A, 9B, 11, 12, 13A to further describe the processes for loading a new set of the edge ring 230 and the support ring 232 into the process volume 106 of the process chamber 100. The method may be stored on and executed by a controller, such as the controller 116.

In block 1702, the factory interface robot 1216, 1218 removes a carrier ring 1302, which includes a new process kit 202, from the storage 1224 and positions the carrier ring and the new process kit 202 on a support disposed in the load lock chamber 1214.

The new process kit 202 may include a new edge ring 230 and a new support ring 232. However, in some cases, it may be desirable to reuse a support ring 232, since it may still have some useable life due to its position relative to the plasma formed in the process chamber.

In block 1704, the transfer robot 1222 picks up the carrier ring 1302 and the new process kit 202, such that the carrier ring 1302 and the new process kit 202 are positioned onto a robot blade 1306 (FIG. 13) coupled to the transfer robot 1222. The transfer robot 1222 then removes the carrier ring 1302 from the load lock chamber 1214. During block 1702 or block 1704, or even in between blocks 1702 and 1704, the load lock chamber 1214 is pumped down to a vacuum pressure that matches the pressure within the vacuum substrate transfer chamber 1212 in which the transfer robot 1222 is disposed.

In block 1706, the transfer robot 1222 then inserts the carrier ring 1302 and the new process kit 202 within the process volume 106 of the process chamber 100. The lift pins 1012 then unmount the process kit 202 from the robot blade 1306 of the transfer robot 1222, which leaves the lift pins 1012 and process kit 202 in a raised position within the process volume 106 of the process chamber 100.

In block 1708, the transfer robot 1222 retracts the robot blade 1306 with the empty carrier ring 1302 disposed thereon from the process volume 106 of the process chamber 100 via the entry port 148.

In block 1710, lift pins 1012, and their associated actuator 1104, lower the edge ring 230 and the support ring 232 of the process kit 202 so that they are positioned on the substrate support 204. Once the process kit 202 is in position, the method 1500 can then be performed on a plurality of semiconductor substrates.

In block 1712, the transfer robot 1222 places the empty carrier ring 1302 within the load lock chamber 1214. Block 1712, along with the subsequently performed blocks 1714-1716, can be performed before or while at least a portion of block 1710 and blocks 1502-1508 of methods 1500 are performed. During block 1712, one or more devices are used to unmount the carrier ring 1302 from the robot blade 1306, and the robot blade 1306 is retracted from the load lock chamber 1214. During block 1712, or after block 1712 is performed, the load lock chamber 1214 is vented to an atmospheric pressure or a pressure that matches the pressure in the environment in which the factory interface robots 1216 and1218 are disposed.

In block 1714, the factory interface robot 1216, 1218 transfers the empty carrier ring 1302 from the load lock chamber 1214 to one of the shelves positioned within the storage 1224.

In block 1716, the transfer robot 1222 places the empty carrier ring 1302 within the storage 1224. The empty carrier ring 1302 will typically remain in the storage 1224 until block 1602 of the method 1500 is ready to be performed at some later time.

Examples of the present disclosure result in increased plasma uniformity across the surface of a substrate being processed in a process chamber in reduced costs for fabricating a process kit. Since there is a direct correlation between plasma uniformity and process yield, the increased plasma uniformity leads to an increase in process yield. Furthermore, edge rings and support rings making use of the present disclosure are at least partially reusable and thus overall cost for plasma processing reduces. Furthermore, loading new and removing used set of rings from process chamber without venting the chamber has a high business and economic impact to customers by improving system yield and reducing manual preventive maintenance and ring placement.

While the foregoing is directed to specific embodiments, other and further embodiments may be devised without departing from the basic scope thereof, and the scope thereof is determined by the claims that follow.

What is claimed is:

1. A process kit for use in a process chamber, comprising:
an annular body, wherein
the annular body has a top surface, a bottom surface, an inner surface, and an outer surface,
the bottom surface is configured to be positioned over a substrate support disposed within a process chamber,
at least a portion of the inner surface, which is positioned between the top surface and the bottom surface, has a diameter that is greater than a diameter of a substrate that is to be processed within the process chamber,
the annular body includes a recess that is defined by a recess bottom surface and a recess edge, wherein the recess edge is disposed between the top surface of the annular body and the recess bottom surface, and wherein the recess bottom surface extends from the inner surface of the annular body, and
the recess edge is disposed a distance from an outer edge of the substrate that is disposed on the substrate support when the substrate is being processed within the process chamber.

2. The process kit according to claim 1, wherein the recess bottom surface is substantially parallel to the bottom surface of the annular body and the recess edge substantially parallel to a central axis of the annular body.

3. The process kit according to claim 1, wherein the recess bottom surface substantially parallel to the bottom surface of the annular body and the recess edge is disposed at an angle with respect to a central axis of the annular body.

4. The process kit according to claim 1, further comprising:
a support ring that has an upper surface that is configured to support a first portion of the bottom surface of the annular body; and
a conductive movable ring that has an upper surface that is configured to support a second portion of the bottom surface of the annular body, wherein the support ring can be positioned within an inner diameter of the conductive movable ring.

5. The process kit according to claim 1, further comprising:
an extended step extending radially-outward from the outer surface of the annular body, wherein a surface of the extended step defines a portion of the top surface.

6. The process kit according to claim 1, wherein the top surface comprises an outer top surface that extends inward from the outer surface, and the annular body further comprises:
a projection that extends above the outer top surface of the annular body, wherein the projection includes a planar top surface and an angled surface that is disposed between the outer top surface of the annular body and the planar top surface of the projection.

7. The process kit according to claim 1, wherein
the annular body comprises a material selected from a group consisting of silicon and silicon carbide that has a bulk resistivity of less than 25 Ohms-cm.

8. A process kit for use in a process chamber, comprising:
a top annular body having a lower interlocking coupling on a bottom surface of the top annular body, wherein
when the top annular body is positioned over at least a portion of a middle annular body configured to be positioned over a substrate support within a process chamber, the lower interlocking coupling engages with an upper interlocking coupling on a top surface of a bottom annual body,
when the top annular body is removed from the middle annular body, the lower interlocking coupling disengages from the upper interlocking coupling on the top surface of the bottom annual body, and
at least a portion of an inner surface of the top annular body has a diameter that is greater than a diameter of a substrate to be processed within the process chamber.

9. The process kit according to claim 8, wherein
the lower interlocking coupling on the bottom surface of the top annular body is a protrusion at least partially extending from the bottom surface of the top annular body towards the bottom surface of the middle annular body, and
the upper interlocking coupling on the top surface of the middle annular body is a depression at least partially extending from the top surface of the middle annular body towards the bottom surface of the middle annular body.

10. The process kit according to claim 8, wherein
the lower interlocking coupling on the bottom surface of the top annular body is a depression at least partially extending from the bottom surface of the top annular body towards the top surface of the top annular body, and
the upper interlocking coupling on the top surface of the middle annular body is a protrusion at least partially extending from the top surface of the middle annular body towards the bottom surface of the top annular body.

11. The process kit according to claim 8, wherein the top annular body is enclosed between side portions on an inner surface and an outer surface of the middle annular body, the side portions extending along a central axis of the middle annular body.

12. The process kit according to claim 8, wherein the top annular body is made of silicon carbide that has a bulk resistivity of less than 25 Ohms-cm.

13. The process kit according to claim 8, wherein
the bottom surface of the top annular body comprises a plurality of first indents,
the top surface of the middle annular body comprises a plurality of second indents,
each first indent is aligned with an opposing second indent, and
an alignment sphere is disposed within a space formed between each of the aligned first and second indents.

14. The process kit according to claim 13, wherein
the alignment sphere is made of quartz, and
a shape of the first and second indents is selected from cone shaped, square shaped, and rectangular shaped.

15. A process kit for use in a process chamber, comprising:
a first annular body configured to be positioned over a substrate support within a process chamber, the first annular body having an upper interlocking coupling on a top surface of the first annular body; and
a second annular body configured to be positioned over at least a portion of the first annular body, the second annular body having a lower interlocking coupling on a bottom surface of the second annular body, wherein
at least a portion of an inner surface of the second annular body has a diameter that is greater than a diameter of a substrate to be processed within the process chamber,
when the second annular body is positioned over at least the portion of the first annular body, the lower interlocking coupling engages with the upper interlocking coupling, and
when the second annular body is removed from the first annular body, the lower interlocking coupling disengages from the upper interlocking coupling.

16. The process kit according to claim 15, wherein
the upper interlocking coupling on the top surface of the first annular body is a depression at least partially extending from the top surface of the first annular body towards the bottom surface of the first annular body, and
the lower interlocking coupling on the bottom surface of the second annular body is a protrusion at least partially extending from the bottom surface of the second annular body towards the bottom surface of the first annular body.

17. The process kit according to claim 15, wherein
the upper interlocking coupling on the top surface of the first annular body is a protrusion at least partially extending from the top surface of the first annular body towards the bottom surface of the second annular body, and
the lower interlocking coupling on the bottom surface of the second annular body is a depression at least partially extending from the bottom surface of the second annular body towards the top surface of the second annular body.

18. The process kit according to claim 15, wherein
the first annular body comprises a first side portion on an inner surface of the first annular body and a second side portion on an outer surface of the first annular body, the first and second side portions extending along a central axis of the first annular body, and
the second annular body is enclosed between the first and second side portions of the first annular body.

19. The process kit according to claim 15, wherein the first and second annular bodies are made of silicon carbide that has a bulk resistivity of less than 25 Ohms-cm.

20. The process kit according to claim 15, wherein
the top surface of the first annular body comprises a plurality of first indents,
the bottom surface of the second annular body comprises a plurality of second indents,
each first indent is aligned with an opposing second indent, and
an alignment sphere is disposed within a space formed between each of the aligned first and second indents.

21. The process kit according to claim 20, wherein
the alignment sphere is made of quartz, and
a shape of the first and second indents is selected from cone shaped, square shaped, and rectangular shaped.
